(19) United States
(12) Patent Application Publication
(10) Pub. No.: US 2026/0167799 A1
(43) Pub. Date: Jun. 18, 2026

(54) METHOD FOR MANUFACTURING COMPOSITE FINE PARTICLES

(71) Applicant: Sharp Display Technology Corporation, Kameyama City, Mie (JP)

(72) Inventor: Yang QU, Kameyama City, Mie (JP)

(21) Appl. No.: 19/125,562

(22) PCT Filed: Dec. 15, 2022
(86) PCT No.: PCT/JP2022/046284

§ 371 Date: Apr. 29, 2025

(51) Int. Cl. C08K 9/08; C09C 3/00; H10K 50/115; H10K 50/17; H10K 50/18

(52) U.S. Cl. CPC C08K 9/08; C09C 3/006; H10K 50/17; H10K 50/18; H10K 50/115

(57) ABSTRACT

A precipitating agent is added to an aqueous solution of a nickel salt to prepare a first slurry of nickel hydroxide fine particles, polyvinylpyrrolidone is added to the first slurry to prepare a second slurry of composite fine particles including nickel hydroxide fine particles and polyvinylpyrrolidone, and composite fine particles are obtained by being separated from the second slurry.

### TECHNICAL FIELD

The disclosure relates to a method for manufacturing composite fine particles, composite fine particles, a light-emitting element, and a display device.

### BACKGROUND ART

Conventionally, various display devices including light-emitting elements have been developed. Examples of the light-emitting elements include organic light emitting diodes (OLEDs), and quantum dot light emitting diodes (QLEDs). The light-emitting element has a layered structure of a light-emitting layer, an electron transport layer, and hole function layers such as a hole injection layer and a hole transport layer.

PTL 1 discloses that polyvinylpyrrolidone is added in order to suppress crystallization in a manufacturing process of an inorganic salt electrochromic thin film material.

### CITATION LIST

### Patent Literature

PTL 1: CN 112213895 A

### SUMMARY OF INVENTION

### Technical Problem

On the other hand, when inorganic metal oxide fine particles having high crystallinity such as nickel oxide are manufactured, the size of the obtained particle is likely to be non-uniform, and it may be difficult to obtain fine particles each having a uniform particle diameter.

An object of an aspect of the disclosure is to provide a new technique for achieving composite fine particles of nickel and a resin.

### Solution to Problem

In order to solve the above-described problem, a method for manufacturing composite fine particles of nickel and polyvinylpyrrolidone according to an aspect of the disclosure includes obtaining a first slurry that is an aqueous slurry of nickel hydroxide fine particles by adding a precipitating agent to an aqueous solution of a nickel salt, obtaining a second slurry that is an aqueous slurry including the nickel hydroxide fine particles and polyvinylpyrrolidone by adding polyvinylpyrrolidone to the first slurry, and obtaining the composite fine particles of the nickel hydroxide fine particles and polyvinylpyrrolidone or composite fine particles of nickel oxide fine particles and polyvinylpyrrolidone by separating the composite fine particles of the nickel hydroxide fine particles and polyvinylpyrrolidone from the second slurry.

In order to solve the above-described problem, a composite fine particle according to an aspect of the disclosure is a composite fine particle of nickel and polyvinylpyrrolidone, the composite fine particle being a core-shell particle including a core particle including a nickel hydroxide fine particle or a nickel oxide fine particle and a shell of polyvinylpyrrolidone configured to cover the core particle.

### Advantageous Effects of Invention

According to an aspect of the disclosure, it is possible to provide a new technique for achieving composite fine particles of nickel and a resin.

### BRIEF DESCRIPTION OF DRAWINGS

FIG. 1 is a flowchart illustrating an example of a flow of steps of a method for manufacturing composite fine particles according to an embodiment of the disclosure.

FIG. 2 is a view schematically illustrating an example of steps of the method for manufacturing composite fine particles according to the embodiment of the disclosure.

FIG. 3 is a plan view schematically illustrating an example of a configuration of a light-emitting element according to the embodiment of the disclosure.

FIG. 4 is a cross-sectional view schematically illustrating a configuration of a display region of a display device according to the embodiment of the disclosure.

FIG. 5 is a cross-sectional view schematically illustrating a configuration of the display region of the display device according to the embodiment of the disclosure.

### DESCRIPTION OF EMBODIMENTS

### Method for Manufacturing Composite Fine Particles

An example of the disclosure relates to a method for manufacturing composite fine particles of nickel and polyvinylpyrrolidone. In the disclosure, a “fine particle” is a particle having a particle diameter of less than a millimeter order (less than 1 mm), for example, a particle of a micro order or a nano order. The particle diameter is, for example, a cumulative particle diameter distribution median diameter D50, and can be measured by, for example, a dynamic light scattering method. Particles that are substantially composed of particles each having a particle diameter of nano order may be referred to as “nanoparticles”.

In the disclosure, the “composite fine particle” refers to a particle configured by integrating nickel and polyvinylpyrrolidone. For example, the “composite fine particle” is a particle obtained by modifying a surface of a nickel particle with polyvinylpyrrolidone, or a core-shell particle composed of a core particle of the nickel particle and a shell of polyvinylpyrrolidone covering the core particle.

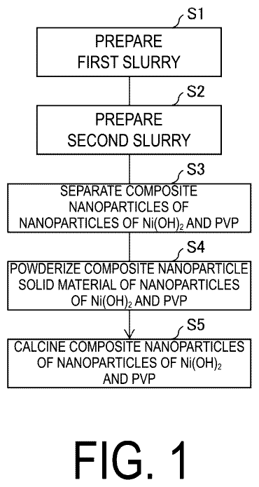

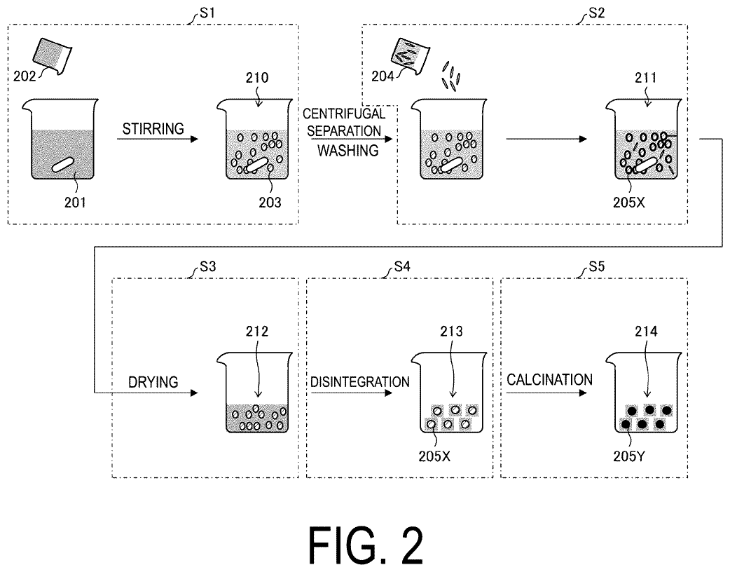

An aspect of a method for manufacturing composite fine particles of the disclosure will be described with reference to FIGS. 1 and 2. The method for manufacturing composite fine particles according to the disclosure includes step S1 of obtaining a first slurry 210, step S2 of obtaining a second slurry 211 that is an aqueous slurry of composite fine particles 205X of nickel hydroxide fine particles 203 and polyvinylpyrrolidone 204 by adding the polyvinylpyrrolidone 204 to the first slurry 210, and a step (separation step) of obtaining composite fine particles of nickel and polyvinylpyrrolidone by separating the composite fine particles 205X from the second slurry.

### Step S1

Step S1 is a preparation of a first slurry and is a step of obtaining the first slurry 210. The first slurry 210 is an aqueous slurry of the nickel hydroxide fine particles 203.

The nickel hydroxide fine particles 203 are particles of a nickel compound that are precipitated and present as particles in an aqueous medium. Examples of the nickel hydroxide fine particles 203 include colloidal fine particles each containing nickel hydroxide as a main component.

The aqueous slurry means a slurry in which a dispersion medium is an aqueous medium, that is, a medium whose main component is water. The dispersion medium of the aqueous slurry may be water itself, or may further contain a dispersion medium that can be mixed with water. Percentage of water in the dispersion medium may be 50% or more, 70% or more, or 80% or more. Examples of a water-soluble component include an organic solvent such as a lower alcohol that can be mixed with water at any ratio, a pH adjuster such as phosphoric acid and carboxylic acid, and a ligand for enhancing the dispersibility of the nickel hydroxide fine particles 203.

The nickel hydroxide fine particles 203 are obtained by adding a precipitating agent 202 to an aqueous solution of a nickel salt 201. The nickel salt 201 may be a salt in which a nickel cation is ionized in the aqueous solution. From the viewpoint of availability and reactivity, the nickel salt 201 is preferably one or more salts selected from the group consisting of nickel nitrate, nickel chloride, nickel sulfate, nickel perchlorate, and nickel carboxylate. From the viewpoint of reactivity, the nickel carboxylate is preferably a nickel carboxylate having 1 to 6 carbon atoms excluding COOH, and nickel acetate is particularly preferable.

The precipitating agent 202 may be selected based on the desired nickel hydroxide fine particles 203. The aqueous slurry in which the nickel hydroxide fine particles 203 are nickel hydroxide fine particles can be produced by an alkali precipitation method. Thus, the precipitating agent 202 is an alkali that can provide hydroxide anions in the aqueous solution. From the viewpoint of availability and reactivity, the precipitating agent that is an alkali is preferably one or more compounds selected from the group consisting of sodium hydroxide, potassium hydroxide, and ammonium hydroxide.

Step S1 can be performed by mixing the aqueous solution of the nickel salt 201 and the precipitating agent 202, and can be performed by, for example, adding the precipitating agent 202 to the aqueous solution of the nickel salt 201 at room temperature (for example, 20° C.). In mixing the aqueous solution of the nickel salt 201 and the precipitating agent 202, a known stirring apparatus such as a magnetic stirrer may be used. The amount of the precipitating agent 202 may be an amount for precipitating a sufficient amount of the nickel hydroxide fine particles 203, and may be 1.5 equivalents or more with respect to nickel in the nickel salt 201. In addition, from the viewpoint of reduction of post-treatment or the like, the amount of the precipitating agent 202 may be 2.5 equivalents or less with respect to nickel of the nickel salt 201. The amount of precipitating agent 202 may be, for example, 2.0 equivalents.

In step S1, the precipitating agent 202 is added to the aqueous solution of the nickel salt 201 to obtain the first slurry 210. Thus, the first slurry 210 containing the nickel hydroxide fine particles 203 each having a fine and uniform particle diameter can be obtained. From the viewpoint of obtaining a good first slurry 210 of the nickel hydroxide fine particles 203, it is preferable to use one or more salts selected from the group consisting of nickel nitrate, nickel chloride, nickel sulfate, nickel carbonate, and nickel carboxylate as the nickel salt 201. In addition, from the viewpoint of obtaining a good first slurry 210 of nickel hydroxide, it is preferable to use one or more compounds selected from the group consisting of sodium hydroxide, potassium hydroxide, and ammonium hydroxide as the precipitating agent 202.

From the viewpoint of more efficiently performing step S2 described below, step S1 may include an additional step. For example, step S1 may further include a concentration step for adjusting a slurry concentration of the nickel hydroxide fine particles 203 in the first slurry. In addition, step S1 may further include a step of separating the precipitated nickel hydroxide fine particles 203 from the slurry and dispersing them in a new dispersion medium to prepare the first slurry 210. Solid-liquid separation of the nickel hydroxide fine particles 203 from the slurry can be performed by a known method such as centrifugal separation or filtration.

According to the manufacturing method of the disclosure, it is possible to obtain the composite fine particles 205X without going through a process in which the nickel hydroxide fine particles 203 are promoted to be crystallized. Thus, when the composite fine particles 205X are solidified, a crystalline solid material is not produced, and a solid material 212 containing the composite fine particles 205X as a main component is disintegrated into a fine powder under a relatively mild condition. Thus, according to the manufacturing method of the disclosure, even poorly-soluble composite fine particles 205X can be obtained in a uniform state. Here, in the disclosure, the “main component” refers to a component contained in the largest amount, for example, a component contained in 50% or more. The “uniform state” of the fine particles refers to a state in which there is little variation in the size, composition, and the like of the fine particle, and can be confirmed from an analysis result by a dynamic light scattering method.

### Step S2

Step S2 is a preparation of a second slurry and is a step of obtaining the second slurry 211. The second slurry 211 is an aqueous slurry of the composite fine particles 205X of the nickel hydroxide fine particles 203 and the polyvinylpyrrolidone 204. Hereinafter, “polyvinylpyrrolidone” is also referred to as “PVP”. “Composite fine particles of the nickel hydroxide fine particles and polyvinylpyrrolidone” is also referred to as “Ni(OH)₂-PVP composite fine particles” and “composite fine particles of the nickel oxide fine particles and polyvinylpyrrolidone” is also referred to as “NiO-PVP composite fine particles”.

The Ni(OH)₂-PVP composite fine particles 205X are obtained by adding the PVP 204 to the first slurry 210. From the viewpoint of causing the PVP 204 to act more uniformly on the nickel hydroxide fine particles 203 in the first slurry 210, in a method for adding the PVP 204, the PVP 204 is preferably added to the first slurry 210 in a state in which the PVP 204 is dissolved with water, a water-soluble organic solvent, or an aqueous solution of the organic solvent.

The PVP 204 may be a homopolymer or a copolymer as long as the effects of the disclosure can be obtained. From the viewpoint of handleability when the Ni(OH)₂-PVP composite fine particles 205X or NiO-PVP composite fine particles 205Y obtained by the manufacturing method of the disclosure are applied to an ink for preparing an electrical function layer in an OLED or a QLED, the molecular weight of PVP is preferably from 10000 to 130000 in number average molecular weight.

Step S2 can be performed by mixing the first slurry 210 and the PVP 204, for example, by adding an aqueous solution of the PVP 204 to the first slurry 210 at room temperature (for example, 20° C.). The mixing may be performed using a known stirring apparatus such as a magnetic stirrer.

From the viewpoint of bringing the PVP 204 into sufficient contact with the nickel hydroxide fine particles 203, the amount of the PVP 204 added to the first slurry 210 is preferably 50 parts by mass or more with respect to 100 parts by mass of the nickel hydroxide fine particles 203 in the first slurry 210. From the viewpoint of suppressing generation of excess PVP 204, the amount of the PVP 204 is preferably 90 parts by mass or less with respect to 100 parts by mass of the nickel hydroxide fine particles 203 in the first slurry 210.

In step S2, while the state of the nickel hydroxide fine particles 203 in the first slurry 210 is maintained, the PVP 204 is added, and the Ni(OH)₂-PVP composite fine particles 205 are obtained. Accordingly, it is considered that the Ni(OH)₂-PVP composite fine particles 205 each have a core-shell structure-like structure in which the surface of the nickel hydroxide fine particle 203 is covered with the PVP 204. Furthermore, in step S2, since the PVP 204 is brought into contact with the fine nickel hydroxide fine particles 203 in the first slurry 210 in the liquid, it is considered that the obtained Ni(OH)₂-PVP composite fine particles 205 each have a structure in which the surface of the nickel hydroxide fine particle 203 is uniformly covered with the PVP 204. By step S2, when the dispersion medium of the second slurry 211 is distilled off to obtain a solid of the composite fine particles 205X in the subsequent steps, the solid is prevented from being strongly solidified due to the strong crystallinity of the nickel salt.

### Separation Step

Next, the composite fine particles 205 are obtained by being separated from the second slurry 211. In the disclosure, the Ni(OH)₂-PVP composite fine particles 205X may be obtained as a final target product, or particles obtained by further processing the Ni(OH)₂-PVP composite fine particles 205X may be obtained as the final target product. Hereinafter, the particles when the Ni(OH)₂-PVP composite fine particles 205X are the particles of the final target product are referred to as the “composite fine particles 205X”, and the particles when the NiO-PVP composite fine particles 205Y obtained by further calcining the composite fine particles 205X are the particles of the final target product are referred to as the “composite fine particles 205Y”.

### Step S3

Step S3 is separation of the composite fine particles of the nickel hydroxide fine particles and PVP, and is a step of obtaining a solid material by drying the second slurry. Step S3 is an example of a mode of obtaining the composite fine particles 205X. Step S3 can be performed by drying and solidifying with a known reduced-pressure drying apparatus such as a vacuum drying oven. In step S3, the composite fine particles 205X are separated as the solid material 212.

### Step S4

Step S4 is powderization of the solid material, and is a step of disintegrating the solid material. Step S4 can be performed using a known pulverizing apparatus that can disintegrate the solid material 212. Examples of the pulverizing apparatus include a motor grinder, a bead mill, a roll mill, and a Lander mill. By step S4, a powder 213 of the composite fine particles 205X can be obtained.

As described above, the solid material 212 has a structure in which the composite fine particles 205X of the nickel hydroxide fine particles 203 and the PVP 204 are included in PVP. Thus, according to step S3 and step S4, the composite fine particles 205X that are the composite fine particles of the nickel hydroxide fine particles 203 and the PVP 204 are obtained by disintegrating the solid material 212 under a mild condition. Since the disintegration of the solid material 212 is achieved under the mild condition, it is considered that in the composite fine particles 205X, the structure composed of the Ni(OH)₂ fine particles and PVP adhering to and covering the surfaces of the fine particles in the aqueous slurry is maintained. Thus, according to step S3 and step S4, uniform and fine composite fine particles 205X can be obtained.

### Step S5

Step S5 is calcination of the composite fine particles (composite fine particles 205X) of the nickel hydroxide fine particles 203 and the PVP 204, and is a step of calcining the composite fine particles obtained by being separated from the second slurry. By further calcining the composite fine particles 205X, the fine particles of Ni(OH)₂ are changed into fine particles of nickel oxide NiO. Thus, in step S5, composite fine particles (composite fine particles 205Y) of the fine particles of NiO and PVP are obtained as a powder 214.

Calcination can be performed by heating the composite fine particles 205X to a temperature at which PVP is not substantially denatured. In the case of obtaining the composite fine particles of NiO fine particles and PVP from the composite fine particles of Ni(OH)₂ fine particles and PVP, from the viewpoint of promoting the dehydration reaction of the Ni(OH)₂ fine particles, a temperature of the calcination is preferably 220° C. or higher, more preferably 250° C. or higher, and still more preferably 270° C. or higher. From the viewpoint of suppressing thermal denaturation of PVP, the temperature of the calcination is preferably 400° C. or less, more preferably 350° C. or less, and still more preferably 300° C. or less.

Step S3 and step S4 or steps S3 to S5 each correspond to a step (separation step) of obtaining the composite fine particles by being separated from the second slurry. According to these steps, uniform and fine composite fine particles 205X of nickel hydroxide or composite fine particles 205Y of nickel oxide can be obtained.

When the nickel-based particles are prepared by a known sol-gel synthesis method, the nickel hydroxide particles are produced as a hydrate and obtained as a solid material in a hard crystalline state. Thus, even when the solid material is pulverized by a mill, particles each having a large particle diameter remain, and it is difficult to obtain uniform and fine nano order particles. Further, even when the solid material is calcined, particles each having a large particle diameter remain. Thus, when any of the nickel hydroxide particles and the nickel oxide particles obtained by such a method are applied to a light-emitting element such as the OLED or the QLED, non-uniformity in the particle diameters may affect the electrical characteristics of the light-emitting element.

In the manufacturing method of the disclosure, as described above, PVP composite nickel-based fine particles are obtained as fine and uniform particles. Thus, according to the above-described steps S1 to S5 in the disclosure, a new technique for achieving the composite fine particles of nickel oxide and a resin is provided.

### MODIFIED EXAMPLES

The above-described separation step may further include a step of classifying the powder 213 of the composite fine particles 205X obtained in step S4. From the viewpoint of obtaining the Ni(OH)₂-PVP composite fine particles each having a fine and a more uniform particle diameter, it is more effective to include such a classification step since coarse particles can be removed.

In addition, in step S5, the calcination may be performed in an atmosphere of an inert gas such as nitrogen. From the viewpoint of suppressing denaturation of PVP during the calcination, the calcination in the inert gas atmosphere is even more effective.

In addition, the separation step described above may be performed together with a spheronization treatment of the composite fine particles 205. For example, the calcination in step S5 may be performed in a fluidized bed, and the spheronization treatment of the composite fine particles 205 may be performed together with the calcination. From the viewpoint of increasing the fluidity of the composite fine particles 205, such a spheronization treatment is more effective.

In the above-described separation step, step S4 and step S5 may be replaced with each other. That is, in the manufacturing method of the disclosure, it is also possible to obtain the composite fine particles of the nickel oxide fine particles and PVP by calcining and then disintegrating the solid material. Alternatively, the solid material may be calcined by heating in the fluidized bed as described above. In this case, since the calcination and the disintegration can be performed at the same time, it is more effective from the viewpoint of reducing the number of steps.

In addition, the separation step may be a step of concentrating the second slurry and fractionating particles by filtration or the like instead of step S3 and step S4. From the viewpoint of obtaining the Ni(OH)₂-PVP composite fine particles each having more uniform PVP content, such a separation step is more effective.

### Composite Fine Particles

The composite fine particle of the disclosure may be a core-shell particle including a core particle containing a nickel hydroxide fine particle or a nickel oxide fine particle and a shell of polyvinylpyrrolidone covering the core particle. According to this configuration, crystallization of the nickel particles can be prevented by polyvinylpyrrolidone around the nickel particles. Thus, the composite fine particles of the disclosure are not crystallized and are excellent in dispersibility.

The core particle includes the nickel hydroxide fine particle or the nickel oxide fine particle. The core particle may include the nickel hydroxide fine particle itself or the nickel oxide fine particle itself in the composite fine particle, or a particle in which the fine particles are unevenly distributed and aggregated in a particle shape. The core particle may be, for example, a primary particle or an aggregated particle of the nickel hydroxide fine particle or the nickel oxide fine particle.

The shell is a portion covering the core particle, and is a portion composed of polyvinylpyrrolidone as a main component. The nickel hydroxide fine particles or the nickel oxide fine particles may be incorporated into the shell during the formation of the shell. Thus, the shell may contain some nickel hydroxide fine particles or nickel oxide fine particles.

The composite fine particles of the disclosure have a peak near a wave number from 1650 cm⁻¹ to 1660 cm⁻¹ and a peak near a wave number from 1280 cm⁻¹ to 1290 cm⁻¹ in absorbance of an infrared absorption spectrum measured by FT-IR. Here, the peak near 1650 cm⁻¹ to 1660 cm⁻¹ is a peak derived from C═O of polyvinylpyrrolidone, and the peak near 1280 cm⁻¹ to 1290 cm⁻¹ is a peak derived from C—N of polyvinylpyrrolidone. Since the composite fine particles of the disclosure have such a peak of absorbance in a fine particle state, it is considered that polyvinylpyrrolidone is complexed with the nickel hydroxide fine particles or the nickel oxide fine particles to such an extent that a specific structure in the composite fine particles is constructed, for example, polyvinylpyrrolidone covers the particles.

The composite fine particles of nickel and polyvinylpyrrolidone of the disclosure can be manufactured by the method for manufacturing the composite fine particles 205 described above. That is, the composite fine particles of nickel and polyvinylpyrrolidone of the disclosure may be the composite fine particles (Ni(OH)₂-PVP composite fine particles) of the nickel hydroxide fine particles and PVP or the composite fine particles (NiO-PVP composite fine particles) of the nickel oxide fine particles and PVP described above.

The Ni(OH)₂-PVP composite fine particles and the NiO-PVP composite fine particles according to an embodiment of the disclosure are considered to be obtained by adding polyvinylpyrrolidone to a slurry of the nickel hydroxide fine particles while maintaining the state of the slurry of the nickel hydroxide fine particles produced by precipitation. This is because it is considered that the solid material of the Ni(OH)₂-PVP composite fine particles and the NiO-PVP composite fine particles obtained by the above-described manufacturing method is easily disintegrated, and thus PVP is composite with the core particles of nickel hydroxide by a stronger interaction in the slurry. As a result, it is considered that the solid material is easily disintegrated into fine particles by pulverization to such an extent that PVP in the solid material is disintegrated.

Note that the composite fine particles of the disclosure each have a particle diameter of at least a micron order, and further can be finer particles of a nano order. Thus, there are circumstances where it is impossible, or perhaps impractical, to directly identify the structure or properties of such fine particles in further detail. For example, it is presumed that the Ni(OH)₂-PVP composite fine particles and the NiO-PVP composite fine particles of the disclosure have the structure to be composite with PVP while maintaining the fineness of the particles at the time of slurry production of the nickel hydroxide fine particles as described above. However, the nickel hydroxide fine particles in the slurry are very fine, and the particle diameter thereof may vary depending on a production condition of the slurry. Thus, at the present time, it is considered to be difficult to further identify in general terms in what state the Ni(OH)₂-PVP composite fine particles and the NiO-PVP composite fine particles including the characteristics at the time of slurry production have above-described characteristics.

There is a possibility that the structures of the Ni(OH)₂-PVP composite fine particles and the NiO-PVP composite fine particles having these characteristics can be identified by comparing and examining the structures of the fine particles in many and various states. However, such identification by comparison and examination requires enormous time and cost, and is considered to be impractical even in view of the fact that rapidity and the like are required due to the nature of the patent application.

The composite fine particles of the disclosure are fine and uniform fine particles. Thus, it is easy to uniformly disperse in various dispersion media. Thus, the composite fine particles of the disclosure can be applied to an ink. The dispersion medium only needs to be able to disperse the composite fine particles of the disclosure, and examples thereof include 1-octanol.

The application of the composite fine particles of the disclosure is not limited to the above-described application, and can be used in a wide range of fields to which the composite fine particles of the disclosure can be applied.

### Light-Emitting Element

The composite fine particles of the disclosure are suitably used as a material of a hole function layer in a light-emitting element. That is, the light-emitting element of the disclosure includes a light-emitting layer, and the hole function layer overlapping the light-emitting layer, and the hole function layer contains the composite fine particles of nickel and polyvinylpyrrolidone described above. The hole function layer in the light-emitting element of the disclosure can be produced by applying the ink of the composite fine particles. As described above, the composite fine particles are fine and uniform particles and are excellent in dispersibility in the dispersion medium. Thus, when the hole function layer is prepared by applying the ink, a uniform hole function layer having no bias in composition, thickness, and the like can be obtained. Thus, a hole function layer exhibiting desired electrical characteristics can be obtained, and according to the disclosure, a light-emitting element having good photoelectric characteristics in the hole function layer can be obtained.

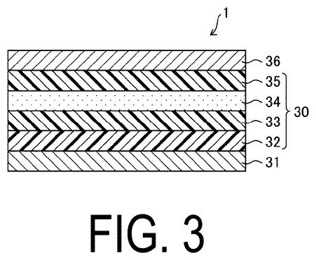

Hereinafter, an example of a configuration of the light-emitting element according to an embodiment of the disclosure will be described with reference to FIG. 3. As illustrated in FIG. 3, the light-emitting element 1 includes a first electrode 31, a second electrode 36, and electrical function layers 30 provided between the first electrode 31 and the second electrode. The electrical function layers 30 include a hole injection layer 32, a hole transport layer 33, a light-emitting layer 34 and an electron transport layer 35. Each of the hole injection layer 32 and the hole transport layer 33 corresponds to the hole function layer. Hereinafter, the light-emitting element will be described on the assumption that the composite fine particles of the disclosure described above are used as a functional material in one or both of the hole injection layer 32 and the hole transport layer 33.

In the present embodiment, the first electrode 31 is also referred to as an anode electrode. The first electrode 31 has electrical conductivity and has optical characteristics of, for example, reflecting part of visible light and transmitting the rest thereof. The first electrode 31 contains both an electrode material that reflects visible light and an electrode material that transmits visible light.

Examples of the electrode material that reflects visible light include metal materials such as Al, Mg, Li and Ag, alloys of these metal materials, layered bodies (for example, ITO/Ag/ITO) of the above metal materials or the above alloys and transparent metal oxides (for example, indium tin oxide (ITO), indium zinc oxide, and indium gallium zinc oxide).

Examples of the electrode material that transmits visible light include a transparent metal oxide, a thin film made of a metal material such as Al and Ag, and a nano wire made of the metal material.

The first electrode 31 can be prepared by a general electrode forming method. Examples of the method for preparing the first electrode 31 include physical vapor deposition (PVD) and chemical vapor deposition (CVD). Examples of the physical vapor deposition include vacuum vapor deposition, sputtering, electron beam (EB) vapor deposition, and ion plating. Examples of the method for patterning the first electrode 31 include photolithography and an ink-jet method.

The hole injection layer (HIL) 32 is made of a hole injection material that can stabilize injection of positive holes into the light-emitting layer 34. Examples of the hole injection material include poly(3,4-ethylene dioxythiophene):polystyrene sulfonic acid (PEDOT:PSS), Ni(OH)₂, NiO, and CuSCN. In one example of the disclosure, the hole injection layer 32 contains the composite fine particles of the disclosure.

The hole transport layer (HTL) 33 is made of a hole transport material that can stabilize transport of positive holes into the light-emitting layer 34. Examples of the hole transport material include poly[(9,9-dioctylfluorenyl-2,7-diyl)-co-(4,4′-(N-(4-sec-butylphenyl))diphenylamine)] (TFB), Ni(OH)₂, NiO, and poly[N,N′-bis(4-butylphenyl)-N,N′-bis(phenyl)-benzidine] (poly-TPD).

The light-emitting layer (EML) 34 is not particularly limited, but is constituted by, for example, quantum dots (QDs). Note that the QD is a dot having a maximum width equal to or less than 100 nm. A shape of the QD may be a spherical three-dimensional shape (circular cross-sectional shape), or may be, for example, a polygonal cross-sectional shape, a rod-shaped three-dimensional shape, a branch-shaped three-dimensional shape, or a three-dimensional shape having unevenness on the surface thereof, or a combination thereof.

The QD may have, for example, a core structure, or may be a core/shell structure, a core/shell/shell structure, or a core/shell with continuously varying ratio structure. The QD may be provided with a ligand. When the QD has the core structure, the ligand may be provided on a surface of the core, and when the QD has the shell structure, the ligand may be provided on a surface of the shell structure.

Examples of a material constituting the core structure of the QD include Si and C in a case of a mono-component system. Examples of the material include CdSe, CdS, CdTe, InP, GaP, InN, ZnSe, ZnS, and ZnTe in a case of a binary system. Examples of the material include CdSeTe, GaInP, and ZnSeTe in a case of a ternary system. Examples of the material include AIGS in a case of a quaternary system.

Examples of a material constituting the shell structure of the QD include CdS, CdTe, CdSe, ZnS, ZnSe, and ZnTe in a case of a binary system. Examples of the material include CdSSe, CdTeSe, CdSTe, ZnSSe, ZnSTe, ZnTeSe, and AIP in a case of a ternary system.

The electron transport layer (ETL) 35 is made of an electron transport material that can stabilize transport of electrons into the light-emitting layer 34. Examples of the electron transport material include fine particles containing one or more elements selected from the group consisting of Zn, Mg, Ti, Si, Sn, W, Ta, Ba, Zr, Al, Y, and Hf.

In the present embodiment, the second electrode 36 is also referred to as a cathode electrode. The second electrode 36 has, for example, electrical conductivity and transparency of visible light. Examples of the electrode material constituting the second electrode 36 include ITO and Ag NanoWires (NW). The second electrode 36 can be made of the electrode material described above for the first electrode 31, and can be prepared by the method described above for the first electrode 31 according to the electrode material. The second electrode 36 is formed on the entire surface of the light-emitting element 1 on a side opposite to the first electrode 31 with the electrical function layer 30 interposed therebetween, and covers the electron transport layer 35, a bank 40, and the thin film transistor layer.

Examples of the light-emitting element include an OLED and a QLED.

### Method for Manufacturing Light-Emitting Element

A method for manufacturing a light-emitting element 1 according to an embodiment of the disclosure includes a step of forming the hole function layer by applying the ink containing the composite fine particles according to the above-described embodiment of the disclosure. In the disclosure, the method for manufacturing the light-emitting element 1 can be performed by a typical method for manufacturing the light-emitting element 1 including the light-emitting layer 34, except for including the applying and forming described above.

The hole function layer can be formed by applying the ink containing the composite fine particles onto a lower layer by a slit coater or an ink-jet. Here, the “lower layer” refers to a layer that has already been formed and is to be applied with the ink. For example, the lower layer of the hole injection layer 32 is the first electrode 31.

The composite fine particles of the disclosure are uniformly dispersed in an ink solvent. Since a solvent having appropriate wettability according to the lower layer is selected as the ink solvent, the ink in which the composite fine particles are uniformly dispersed is uniformly applied onto the light-emitting layer 34. Thus, the uniform hole function layer with the composite fine particles is formed.

### Display Device 100

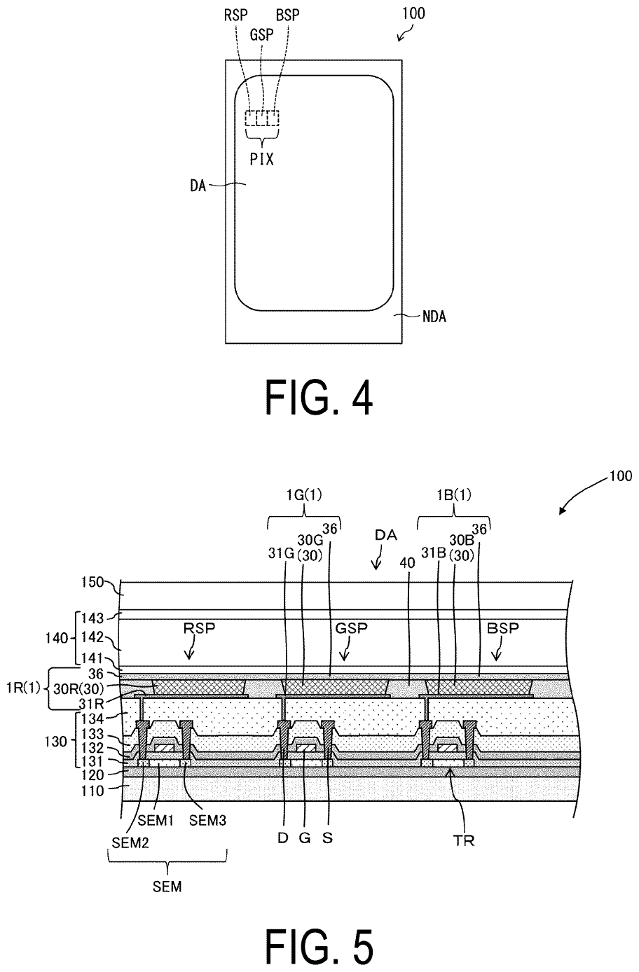

A display device that is an example of the disclosure includes a substrate, and the above-described light-emitting element disposed on the substrate. FIG. 4 illustrates an example of the display device. FIG. 4 is a plan view schematically illustrating a configuration of the display device according to an embodiment of the disclosure. As illustrated in FIG. 4, a display device 100 includes a frame region NDA and a display region DA. A plurality of pixels PIX are provided in the display region DA of the display device 100, and each pixel PIX includes a red subpixel RSP, a green subpixel GSP, and a blue subpixel BSP to which the light-emitting element 1 is applied. For more information, the red subpixel RSP includes the red light-emitting element 1R, the green subpixel GSP includes the green light-emitting element 1G, and the blue subpixel BSP includes the blue light-emitting element 1B. The light-emitting element of each color may have a configuration of the light-emitting element 1 in FIG. 3 and may have a similar configuration except for a material of the light-emitting layer 34. The configuration of the pixel of the display device in the disclosure is not limited to the above-described configuration. For example, one pixel PIX may further include a subpixel of another color.

The display device 100 may include a barrier layer, a thin film transistor, and the light-emitting element 1 in this order on the substrate. The electrical function layer 30 in the light-emitting element 1 may be disposed by layering the hole injection layer 32, the hole transport layer 33, the light-emitting layer 34, and the electron transport layer 35 in this order from the thin film transistor side.

The display device 100 is not limited thereto and may include an additional layer. For example, a sealing layer or a function film may be included on the light-emitting element 1. Disposition of the light-emitting element 1 is not particularly limited. For example, the bank may be disposed so as to partition the light-emitting element 1 in a plan view. As long as the light-emitting element 1 contains the composite fine particles according to the embodiment of the disclosure, other configurations may be optionally changed.

FIG. 5 is a cross-sectional view schematically illustrating a configuration of a display region of the display device 100. As illustrated in FIG. 5, in the display region DA of the display device 100, a barrier layer 120, a thin film transistor layer 130 including transistors TR, a red light-emitting element 1R, a green light-emitting element 1G, a blue light-emitting element 1B, and a bank (transparent resin layer) 40, a sealing layer 140, and a function film 150 are provided on a substrate 110.

Note that a configuration in which the substrate 110, the barrier layer 120, and the thin film transistor layer 130 illustrated in FIG. 5 are provided in this order from the substrate 110 side is also referred to as an “active matrix substrate”.

The red subpixel RSP includes the red light-emitting element 1R, the green subpixel GSP includes the green light-emitting element 1G, and the blue subpixel BSP includes the blue light-emitting element 1B. The light-emitting element 1 of each color has a similar configuration except for a material of the light-emitting layer.

The substrate 110 may be, for example, a resin substrate made of a resin material such as polyimide, or may be a glass substrate.

The barrier layer 120 is a layer that prevents foreign matters such as water and oxygen from entering the transistors TR, the red light-emitting element 1R, the green light-emitting element 1G, and the blue light-emitting element 1B. For example, the barrier layer 120 may include a silicon oxide film, a silicon nitride film, or a silicon oxynitride film formed by CVD, or a layered film thereof.

The thin film transistor layer 130 includes a portion including the transistor TR and a portion not including the transistor TR. At a portion other than the portions including the transistors TR in the thin film transistor layer 130, inorganic insulating films 131 to 133 and a flattening film 134 overlap each other in this order from the substrate 110 side. The portion including the transistor TR in the thin film transistor layer 130 includes a semiconductor film SEM, the inorganic insulating film 131, a gate electrode G, the inorganic insulating film 132, the inorganic insulating film 133, a source electrode S, a drain electrode D, and the flattening film 134. The semiconductor film SEM includes a drain region SEM2 and a source region SEM3 that are doped with an impurity such as P (phosphorus), and a channel region SEM1 between the drain region SEM2 and the source region SEM3.

The inorganic insulating films 131 to 133 can be constituted by, for example, a silicon oxide film, a silicon nitride film, or a silicon oxynitride film formed by CVD, or a layered film thereof. The inorganic insulating films 131 to 133 may be of the same type or different types.

The flattening film 134 can be made of a coatable organic material such as polyimide and acrylic.

The semiconductor film SEM is made of, for example, low-temperature polysilicon (LTPS) or may be made of an oxide semiconductor (for example, an In—Ga—Zn—O based semiconductor). In the present embodiment, the transistor TR has, for example, a top gate structure. Note that in the disclosure, the transistor TR may have a bottom gate structure.

The gate electrode G, the source electrode S, and the drain electrode D are all constituted by a single layer film or a layered film of a metal. Examples of the metal include aluminum, tungsten, molybdenum, tantalum, chromium, titanium and copper.

Note that the thin film transistor layer 130 is provided with a control circuit including the transistors TR each of which controls a respective one of the red light-emitting element 1R, the green light-emitting element 1G, and the blue light-emitting element 1B that respectively correspond to the red subpixel RSP, the green subpixel GSP, and the blue subpixel BSP.

The red light-emitting element 1R includes a first electrode 31R that is an upper layer overlying the flattening film 134, an electrical function layer 30R including the red light-emitting layer, and a second electrode 36 in this order in the layering direction. Similarly, the green light-emitting element 1G includes a first electrode 31G that is an upper layer overlying the flattening film 134, an electrical function layer 30G including the green light-emitting layer, and the second electrode 36 in this order in the layering direction. The blue light-emitting element 1B also includes a first electrode 31B that is an upper layer overlying the flattening film 134, an electrical function layer 30B including the blue light-emitting layer, and the second electrode 36 in this order in the layering direction.

The sealing layer 140 is a transparent film and, for example, may be constituted by an inorganic sealing film 141 covering the second electrode 36, an organic film 142 that is an upper layer overlying the inorganic sealing film 141, and an inorganic sealing film 143 that is an upper layer overlying the organic film 142. The sealing layer 140 prevents foreign matters such as water and oxygen from penetrating into the red light-emitting element 1R, the green light-emitting element 1G, and the blue light-emitting element 1B.

Here, each of the inorganic sealing film 141 and the inorganic sealing film 143 is an inorganic film and can be constituted by, for example, a silicon oxide film, a silicon nitride film, a silicon oxynitride film, or a layered film thereof. The inorganic film is formed by CVD, for example. The organic film 142 is a transparent organic film having a flattening effect, and can be made of a coatable organic material such as acrylic, for example.

The function film 150 is a film with at least one function selected from the group consisting of an optical compensation function, a touch sensor function, and a protection function, for example.

By configuring the display device 100 as described above, the hole function layer stably outputs desired electrical characteristics. Thus, a display device that can stably output an image having desired electrical characteristics and image quality is achieved.

The disclosure is not limited to the embodiments described above, and various modifications may be implemented within a range not departing from the scope of the claims. Embodiments obtained by appropriately combining technical approaches disclosed in each of the different embodiments also fall within the scope of the technology of the disclosure. Furthermore, novel technical features can be formed by combining the technical approaches disclosed in the embodiments.

According to the configurations of the disclosure, more stable and higher image quality is achieved in a display device with low power consumption, and contribution to achievement of sustainable development targets (SDGs) related to education, welfare, life, and industry is expected.

### EXAMPLE

Examples of the disclosure will be described below.

### Preparation of Composite Fine Particles of Nickel Hydroxide and Polyvinylpyrrolidone

An aqueous solution of 2.5 M nickel nitrate (Ni(NO₃)₂) was added to an aqueous solution of 10 M sodium hydroxide (NaOH). A sodium hydroxide aqueous solution was added until a mixed solution became pH 10. The mixed solution was stirred with a magnetic stirrer to obtain the first slurry in which nickel hydroxide was precipitated. On the other hand, an aqueous solution of polyvinylpyrrolidone in an amount of 2.5 times equivalent to nickel nitrate was prepared.

The first slurry was subjected to centrifugal separation and water washing several times to remove water-soluble nitrate as a by-product, thereby purifying nickel hydroxide. Thereafter, water was added to the purified nickel hydroxide to form an aqueous slurry, and an aqueous solution of polyvinylpyrrolidone was added thereto in an amount of 2.5 equivalent parts to 100 parts by mass of nickel hydroxide, followed by stirring for 24 hours to obtain a second slurry containing the composite fine particles of nickel hydroxide and polyvinylpyrrolidone. The second slurry was dried at 80° C. for 24 hours or more to obtain a solid material 1 of the composite fine particles and polyvinylpyrrolidone.

### Evaluation of Composite Fine Particles

On the other hand, the purified aqueous slurry of the nickel hydroxide fine particles was dried as it was at 80° C. for 24 hours or more to prepare a solid material 2 of the nickel hydroxide fine particles.

Here, the hardness of the solid material 1 and the solid material 2 was evaluated. The hardness of the solid material was evaluated by selecting an index considered to be applicable from eight stage indexes each represented by a type of a sample. The eight stage indexes are “very hard”, “hard and brittle”, “slightly hard”, “soft”, “brittle”, “fibrous”, “weak to heat”, and “containing moisture”.

According to these indexes, the solid material 1 can be evaluated as a “brittle” or “soft” solid material. The “brittle” can be expressed as a hardness comparable to, for example, some alloys, ceramics, salt, tablets, silicon carbide, coke, coal, and frozen plastics (a phenolic resin, rubber, an acrylic resin, or the like). The “soft” can be expressed as a hardness comparable to, for example, cereals, gypsum, salt, talc, feed, graphite, leaves, grasses, pigments, spices, sugar-coated tablets, mica, and the like.

On the other hand, the solid material 2 can be evaluated as a “slightly hard” or “hard and brittle” solid material. The “slightly hard” can be expressed as a hardness comparable to, for example, glass, cement, calcite, coal, ash, sludge, catalysts, soil, tablets, fertilizer, pellets, and the like. The “hard and brittle” can be expressed as a hardness comparable to, for example, slag, quartz, rock, bauxite, carborundum, and the like.

Next, the solid material 1 was disintegrated in a mortar to obtain a powder 1. Since the solid material 1 was the brittle solid, it was easy to be disintegrated. Further, the particles constituting the powder 1 were fine and uniform particles. In addition, after the powder 1 was dispersed in an aqueous solution, it was confirmed from the result of analysis by a dynamic light scattering analyzer (DLS) that the powder 1 was nanoparticles substantially composed of nano order particles.

On the other hand, since the solid material 2 was a hard solid, the disintegration was not easy. In addition, coarse particles were clearly scattered in the powder 2. When the powder 2 was observed with an optical microscope, not only nano order particles but also micron order particles were confirmed. The evaluation results are shown in Table 1.

TABLE 1

| | Solid material 1 | Solid material 2 |
|---|---|---|
| State before disintegration | Soft or brittle | Slightly hard or hard |
| | | and brittle |
| Ease of disintegration | Easy | Not easy |
| Powder after disintegration | Fine and uniform | Non-uniform particles |
| | particles | mixed with large grains |

The powder 1 and the powder 2 were each calcined at 265° C. for 2 hours to obtain the composite fine particles of the nickel oxide fine particles and polyvinylpyrrolidone. Even after calcination, depending on the shape of the powder before calcination, after dispersion in an aqueous solution, from the results of analysis with a dynamic light scattering analyzer (DLS), the composite fine particles of nickel oxide and polyvinylpyrrolidone obtained by calcination of the powder 1 were uniform and fine particles, but the fine particles of nickel oxide obtained by calcination of the powder 2 were non-uniform particles mixed with large particles.

### DISCUSSION

The powder 1 was an aggregate of fine and uniform particles, regardless of being calcined. This is considered to be because polyvinylpyrrolidone was caused to act on the nickel-containing colloid fine particles mainly containing nickel hydroxide in a slurry state, so polyvinylpyrrolidone was present around the fine nickel-containing colloid fine particles in the solid material from which the dispersion medium was removed, and the solid material was disintegrated into the state of fine particles at the time of slurry even under a mild disintegrating condition.

On the other hand, the powder 2 was an aggregate of particles each having a non-uniform size including particles each having a large particle diameter, regardless of being calcined. This is considered to be because the slurry of the nickel-containing colloid fine particles mainly containing nickel hydroxide was solidified as it was, so the nickel-containing colloid fine particles were strongly solidified due to the strength of the crystallinity of the fine particles, and the solid material was not finely and uniformly disintegrated to a size of nano order by disintegration under a mild condition.

### INDUSTRIAL APPLICABILITY

The disclosure is expected to be used for manufacturing fine and uniform nano order particles in composite particles of inorganic particles having strong crystallinity and an organic component such as a resin.

### REFERENCE SIGNS LIST

1 Light-emitting element
30 Electrical function layer
31 First electrode
32 Hole injection layer
33 Hole transport layer
34 Light-emitting layer
35 Electron transport layer
36 Second electrode
40 Bank
100 Display device
110 Substrate
120 Barrier layer
130 Thin film transistor layer
131, 132, 133 Inorganic insulating film
134 Flattening film
140 Sealing layer
141, 143 Inorganic sealing film
142 Organic film
150 Function film
201 Nickel salt
202 Precipitating agent
203 Nickel hydroxide fine particles
204 Polyvinylpyrrolidone
205 Composite fine particles of nickel and polyvinylpyrrolidone (composite fine particles)
210 First slurry
211 Second slurry
212 Solid material
213 Powder of composite fine particles 205X
214 Powder of composite fine particles 205Y

1. A method for manufacturing composite fine particles of nickel and polyvinylpyrrolidone, the method comprising:
obtaining a first slurry that is an aqueous slurry of nickel hydroxide fine particles by adding a precipitating agent to an aqueous solution of a nickel salt;
obtaining a second slurry that is an aqueous slurry including the nickel hydroxide fine particles and polyvinylpyrrolidone by adding polyvinylpyrrolidone to the first slurry; and
obtaining the composite fine particles of the nickel hydroxide fine particles and polyvinylpyrrolidone or composite fine particles of nickel oxide fine particles and polyvinylpyrrolidone by separating the composite fine particles of the nickel hydroxide fine particles and polyvinylpyrrolidone from the second slurry,
wherein the obtaining the composite fine particles further includes
obtaining a solid material by drying the second slurry and
disintegrating the solid material.

2. (canceled)

3. The method for manufacturing composite fine particles according to claim 1,
wherein the obtaining the composite fine particles further includes calcining the composite fine particles of the nickel hydroxide fine particles and polyvinylpyrrolidone separated from the second slurry.

4. The method for manufacturing composite fine particles according to claim 1,
wherein one or more compounds selected from the group consisting of sodium hydroxide, potassium hydroxide, and ammonium hydroxide are used as the precipitating agent.

5. The method for manufacturing composite fine particles according to claim 1,
wherein one or more salts selected from the group consisting of nickel nitrate, nickel chloride, nickel sulfate, and nickel carboxylate are used as the nickel salt.

6. (canceled)

7. (canceled)

8. (canceled)
